(19) United States
(12) Patent Application Publication
(10) Pub. No.: US 2025/0264499 A1
(43) Pub. Date: Aug. 21, 2025

(54) HYPOCHLORITE CELL VOLTAGE MONITORING DEVICE

(71) Applicant: Saudi Arabian Oil Company, Dhahran (SA)

(72) Inventors: Abduladeem Asiri, Tarut (SA); Zaid Ali, Qatif (SA)

(21) Appl. No.: 18/444,899

(22) Filed: Feb. 19, 2024

(51) Int. Cl. G01R 1/04; G01R 13/02; G01R 19/25

(52) U.S. Cl. CPC G01R 1/0408; G01R 13/0209; G01R 19/2503

(57) ABSTRACT

A hypochlorite cell voltage monitoring device for monitoring the voltage across a hypochlorite cell. The hypochlorite cell voltage monitoring device includes a housing, a clamp having a first clamp ring and a second clamp ring opposite the first clamp ring, and digital direct current (DC) voltmeter disposed in the housing. The first clamp ring couples to an anode side of the hypochlorite cell and the second clamp ring couples to a cathode side of the hypochlorite cell. The voltage across the hypochlorite cell may be monitored using the digital direct current (DC) voltmeter.

### BACKGROUND

### Field of the Disclosure

The present disclosure generally relates to the treatment of water such as in water treatment plants. More specifically, embodiments of the disclosure relate to the production of chlorine by hypochlorite generators for use in seawater treatment.

### Description of the Related Art

Seawater is an easily-available resource that may be used for various purposes and in a variety of different applications. For example, seawater may be used to support and sustain crude oil and gas production, such as for use in reservoir pressure maintenance via the injection of seawater. The seawater may be pumped into a processing plant from a source such as a sea or ocean, then transported via pipelines to oilfields or to other plants for further processing. The processing of seawater may include treatment with a disinfecting agent such as chlorine, the useful species of which include hypochlorous acid, hypochlorite, and chlorine. However, the generation of chlorine for seawater treatment and the maintenance of such systems may be time-consuming and expensive.

### SUMMARY

Hypochlorite generators may be used in seawater treatment plants to produce chlorine. A hypochlorite generator may include hypochlorite cells having an electrode (for example, a bipolar electrode) to generate sodium hypochlorite using direct current (DC) applied to the cell via the electrode.

The voltage across each cell (also referred to as the “operating voltage”) in a hypochlorite generator is an important indicator of proper function of the generator. When operating normally, a hypochlorite cell may have a voltage drop that is within a certain percentage of the applied voltage. Voltage readings are typically performed manually and periodically (for example, once a month) using a DC digital voltmeter to measure voltage cell-by-cell. However, this process is time-consuming and requires a significant amount of personnel. Moreover, the process exposes personnel to live voltages and thus requires additional safety equipment and procedures.

Embodiments of the disclosure include a hypochlorite cell voltage monitoring device and processes for using and manufacturing the device. Advantageously, the device eliminates the possibility of electric shock from a monitored hypochlorite cell and does not require an external power source such as a battery. The hypochlorite cell voltage monitoring device reduces the time and manpower required to manually and periodically monitor the voltage across a hypochlorite cell and may improve the safety of monitoring operations by eliminating the exposure of personal to live voltages.

In one embodiment, a hypochlorite cell voltage monitoring device for monitoring voltage across a hypochlorite cell is provided. The hypochlorite cell voltage monitoring device includes a clamp having a first clamp ring having a first voltage receiver and a second clamp ring opposite the first clamp ring and having a second voltage receiver, such that the first clamp ring has a diameter selected to clamp to a first side of a hypochlorite cell and the second clamp ring has a diameter selected to clamp to a second side of the hypochlorite cell. The hypochlorite cell voltage monitoring device also includes a housing adjacent to the clamp and having a first side and a second side opposite the first side, and a digital direct current (DC) voltmeter disposed in the first side of the housing, and electrically connected to the first voltage receiver and the second voltage receiver such that the digital direct current (DC) voltmeter is operable to measure a voltage across the first voltage receiver and the second voltage receiver and the digital direct current (DC) voltmeter includes a display.

In some embodiments, the clamp and the housing are formed as a single component. In some embodiments, the clamp is formed from a polymer. In some embodiments, the housing is formed from a polymer. In some embodiments, the first clamp ring and the second clamp ring each includes a hinge and a fastener coupled to the hinge. In some embodiments, the first clamp ring and second clamp ring each includes an interlocking portion opposite the hinge. In some embodiments, the hypochlorite cell voltage monitoring device does not include a power source.

In another embodiment, a method of monitoring voltage across a hypochlorite cell is provided. The method includes attaching a first clamp ring of a clamp of a hypochlorite cell voltage monitoring device to a first side of the hypochlorite cell and attaching a second clamp ring of the clamp of the hypochlorite cell voltage monitoring device to the second side of the hypochlorite cell. The hypochlorite cell voltage monitoring device includes the clamp having the first clamp ring having a first voltage receiver and the second clamp ring having a second voltage receiver and a housing adjacent to the clamp and having a first side and a second side opposite the first side. The hypochlorite cell voltage monitoring device also includes a digital direct current (DC) voltmeter disposed in the first side of the housing, and electrically connected to the first voltage receiver and the second voltage receiver such that the digital direct current (DC) voltmeter is operable to measure a voltage across the first voltage receiver and the second voltage receiver and the digital direct current (DC) voltmeter has a display. The method further includes monitoring the voltage across the hypochlorite cell on the display of the digital DC voltmeter.

In some embodiments, the clamp and the housing are formed as a single component. In some embodiments, the clamp is formed from a polymer. In some embodiments, the housing is formed from a polymer. In some embodiments, the first clamp ring and the second clamp ring each includes a hinge and a fastener coupled to the hinge. In some embodiments, the first clamp ring and second clamp ring each includes an interlocking portion opposite the hinge. In some embodiments, the hypochlorite cell voltage monitoring device does not include a power source and the method includes powering the hypochlorite cell voltage monitoring device using the hypochlorite cell. In some embodiments, the hypochlorite cell is a first hypochlorite cell and the method includes detaching the first clamp ring of the clamp of the hypochlorite cell voltage monitoring device from the first side of the first hypochlorite cell, detaching the second clamp ring of the clamp of the hypochlorite cell voltage monitoring device from the second side of the hypochlorite cell, attaching the first clamp ring of a clamp of a hypochlorite cell voltage monitoring device to a first side of a second hypochlorite cell, attaching a second clamp ring of the clamp of the hypochlorite cell voltage monitoring device to the second side of a second hypochlorite cell, and monitoring the voltage across the second hypochlorite cell on the display of the digital DC voltmeter.

In another embodiment, a method of manufacturing a hypochlorite cell voltage monitoring device for monitoring voltage across a hypochlorite cell. The method includes printing, using a three-dimensional printer, a single component having a clamp and a housing, the clamp having a first clamp ring and a second clamp ring opposite the first clamp ring, such that the first clamp ring has a diameter selected to clamp to a first side of the hypochlorite cell and the second clamp ring has a diameter selected to clamp to a second side of the hypochlorite cell, and the housing includes a first side and a second side opposite the first side. The method also includes installing a first voltage receiver in the first clamp ring and a second voltage receiver in the second clamp ring, installing a digital direct current (DC) voltmeter in the housing, and electrically connecting the digital DC voltmeter to the first voltage receiver and second voltage receiver.

In some embodiments, the clamp and the housing are formed from a polymer. In some embodiments, the first clamp ring and second clamp ring each has a hinge and a fastener coupled to the hinge. In some embodiments, the first clamp ring and second clamp ring each includes an interlocking portion opposite the hinge. In some embodiments, the hypochlorite cell voltage monitoring device does not include a power source.

### BRIEF DESCRIPTION OF THE DRAWINGS

FIG. 1 is a schematic drawing depicting a perspective view of a hypochlorite cell voltage monitoring device in accordance with an embodiment of the disclosure;

FIG. 2 is a schematic drawing depicting a side view of the hypochlorite cell voltage monitoring device of FIG. 1 in accordance with an embodiment of the disclosure;

FIG. 3 is a schematic drawing depicting a top view of the hypochlorite cell voltage monitoring device of FIG. 1 in accordance with an embodiment of the disclosure;

FIG. 4 is a schematic drawing depicting a side view of the hypochlorite cell voltage monitoring device of FIG. 1 in accordance with an embodiment of the disclosure;

FIG. 5 is a process for manufacturing and using a hypochlorite cell voltage monitoring device in accordance with an embodiment of the disclosure;

FIG. 6 is a drawing depicting an example hypochlorite cell voltage monitoring device coupled to a hypochlorite cell in accordance with an embodiment of the disclosure; and

FIG. 7 is a drawing depicting the example hypochlorite cell voltage monitoring device of FIG. 6 in accordance with an embodiment of the disclosure.

### DETAILED DESCRIPTION

The present disclosure will be described more fully with reference to the accompanying drawings, which illustrate embodiments of the disclosure. This disclosure may, however, be embodied in many different forms and should not be construed as limited to the illustrated embodiments. Rather, these embodiments are provided so that this disclosure will be thorough and complete, and will fully convey the scope of the disclosure to those skilled in the art.

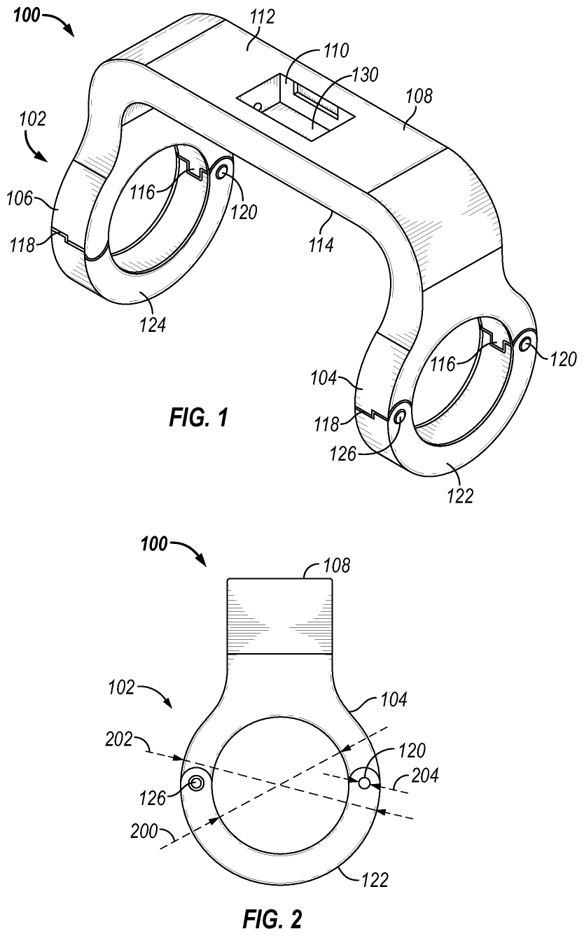

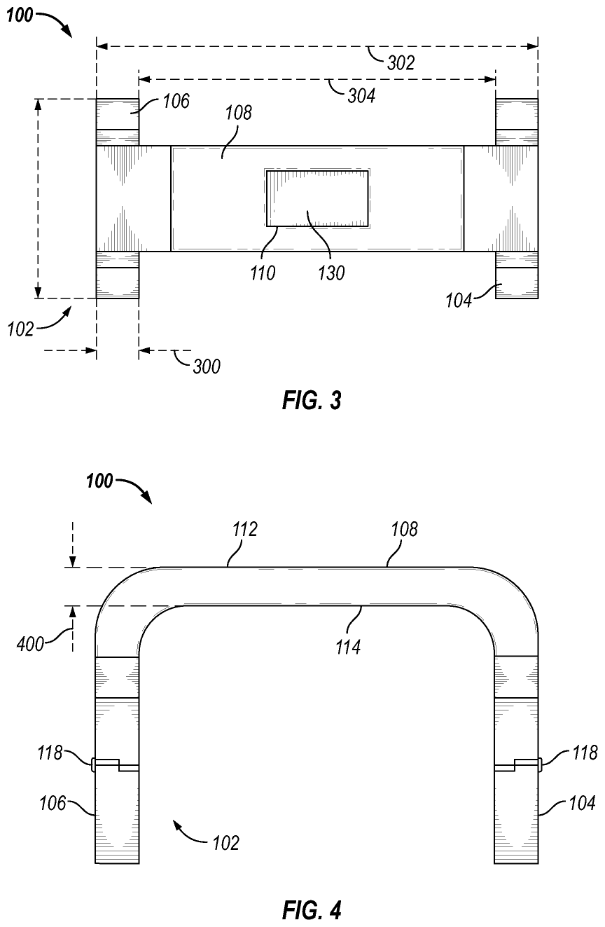

FIGS. 1-4 depicts various views of a hypochlorite cell voltage monitoring device 100 in accordance with an embodiment of the disclosure. FIG. 1 illustrates a perspective view of the hypochlorite cell voltage monitoring device 100, FIG. 2 illustrates a side view of the hypochlorite cell voltage monitoring device 100, FIG. 3 illustrates a top view of the hypochlorite cell voltage monitoring device 100, and FIG. 4 illustrates a front view of the hypochlorite cell voltage monitoring device 100. It should be appreciated that the dimensions shown in FIGS. 1-4 and described infra are merely provided by way of example and other embodiments of hypochlorite cell voltage monitoring device 100 may include different dimensions.

As shown in FIGS. 1-4, the hypochlorite cell voltage monitoring device 100 includes a clamp 102 having a first clamp ring 104 and a second clamp ring 106 opposite the first clamp ring 104, a housing 108 that connects both sides (that is, both clamp rings) of the clamp 102, and a digital DC voltmeter 110 disposed in the housing 102. As shown in FIG. 1, the ends of the housing 108 are adjacent to the clamp rings 104 and 106 of the clamp 102. In some embodiments, the housing 108 has a generally rectangular shape with rounded corners at each longitudinal end to form the ends adjacent the clamp 102. As also shown in FIG. 1, the housing 108 includes a first side 112 and a second side 114 opposite the first side, such that the digital DC voltmeter 110 is located at the first side 112 of the housing 108 and the clamp rings 104 and 106 extend in a direction generally perpendicular to the center planar portion of the second side 114 of the housing 108.

The clamp 102 may be formed from a non-conductive polymer. The first clamp ring 104 may include an anode voltage receiver located inside the clamp ring 104 for measuring voltage at an anode of a hypochlorite cell. The second clamp ring 106 may include a cathode voltage receiver located inside the clamp ring 104 for measuring voltage at a cathode of a hypochlorite cell. The anode voltage receiver and the cathode voltage receiver may be formed of a conductive materials. In some embodiments, the conductive material is brass metal.

Each clamp ring 104 and 106 includes a hinge 116 one side of the ring and interlocking portion 118 on the other side of the ring. Each hinge 116 includes a receptable 120 for receiving a fastener (for example, a screw or a pin) to secure the hinge 116 and enable movement of a lower portion of the clamp ring. For example, the clamp ring 104 may be opened by moving the lower portion 122 of the clamp ring 104 via the hinge 116 and may be closing by moving the lower portion 122 of the clamp ring 104 until the interlocking portion 118 couples together. Similarly, the clamp ring 106 may be opened by moving the lower portion 124 of the clamp ring 106 via the hinge 114 and may be closed by moving the lower portion 124 of the clamp ring 106 until the interlocking portion 118 couples together. In some embodiments, the interlocking portion 118 may include a receptable 126 for receiving a fastener (for example, a screw or a pin) to further secure the portion 118.

The housing 108 be formed from the same material as the clamp 102 and may be formed from a non-conductive polymer. In some embodiments, the housing 108 and the clamp 102 may be formed as a single component, such as by three-dimensional (3D) printing using a polymer 3D printing filament.

The digital DC voltmeter 110 may be disposed in the housing 102 and may include a display 130. The digital DC voltmeter 110 may be electrically connected to the anode voltage receiver located inside the clamp ring 104 and the cathode voltage receiver located inside the clamp ring 104 such that the digital DC voltmeter 110 is powered by the anode-cathode circuit formed when the hypochlorite cell voltage monitoring device 100 is clamped to a hypochlorite cell. The hypochlorite cell voltage monitoring device 100 thus does not include a power source such as a battery.

As mentioned supra, FIG. 2 is a side view of the hypochlorite cell voltage monitoring device 100 in accordance with an embodiment of the disclosure. The side view depicts the clamp 102 and clamp ring 104, housing 108, and lower portion 122. Additionally, the side view further illustrates the receptacles 120 and 126 for receiving respective fasteners. As shown in FIG. 2, the clamp 104 includes an inner diameter 200 and outer diameter 202. As also shown in FIG. 2, the receptable 120 has a receptable diameter 204. In some embodiments, the inner diameter 200 is 63.5 millimeters (mm) and the outer diameter is 93.5 mm. In some embodiments, the receptable diameter is 5 mm. In some embodiments, the second clamp 106 may have the same outer diameter, inner diameter, and receptable diameter as the first clamp 104.

As also mentioned infra, FIG. 3 is a top view of the hypochlorite cell voltage monitoring device 100 in accordance with an embodiment of the disclosure. The top view shown in FIG. 3 further illustrates the clamp 102, the housing 104, and the digital DC voltmeter 110 having the display 130. The display 130 may depict the voltage measured by the hypochlorite cell voltage monitoring device 100 when clamped to a hypochlorite cell. As shown in FIG. 3, each clamp ring 104 and 106 may have a thickness 300, the hypochlorite cell voltage monitoring device 100 may have a length 302, and the housing 108 may have a width 304. In some embodiments, the thickness is 20 mm, the length 302 is 210 mm, and the width is 50 mm.

As also noted supra, FIG. 4 illustrates a front view of the hypochlorite cell voltage monitoring device 100 in accordance with an embodiment of the disclosure. The front view shown in FIG. 4 further illustrates the clamp 102 and clamp rings 104 and 106, the housing 108, and the interlocking portion 118. FIG. 4 also depicts the height 400 of the housing 108. In some embodiments, the height 400 may be 20 mm. FIG. 4 also depicts the features of the housing 108 in clearer detail. The housing 108 includes corners 402 that gradually curve to the ends of housing adjacent to the clamp rings 104 and 106. As shown in FIG. 4, the clamp 102 with the clamp rings 104 and 106 extends substantially perpendicular from the center planar portion of the second side 114. In other embodiments, the clamp rings 104 and 106 may extend at an angle from the center planar portion of the second side 114 as long as the clamp rings 104 and 106 remain able to attach to the anode and cathode sides of a hypochlorite cell.

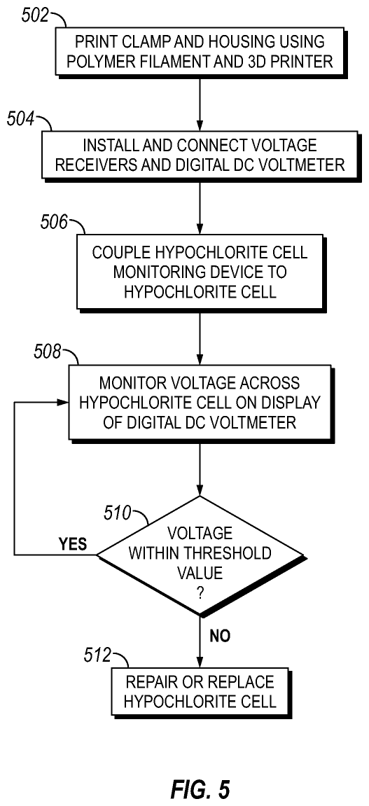

FIG. 5 is a flowchart of a process 500 for making and using a hypochlorite cell voltage monitoring device in accordance with an embodiment of the disclosure. Initially, a housing and clamp may be manufactured such as by 3D printing using a suitable polymer and 3D printer (block 502). In some embodiments, the clamp and housing may be printed as a single component. In some embodiments, the interlocking portion of the clamp rings may be printed separately and coupled via the hinge and fastener discussed supra. In some embodiments, the 3D printer may print the clamp and housing with voids sufficient to install voltage receivers and the digital DC voltmeter. In some embodiments, the polymer used to print the housing and clamp may be acrylonitrile butadiene styrene (ABS), polylactic acid (PLA), or polycarbonate (PC).

Voltage receivers may be installed in the clamp and a digital DC voltmeter may be installed the housing, and the voltage receivers may be electrically connected to the digital DC voltmeter (block 504). In some embodiments, a fastener may be inserted into the hinges of the clamp to complete assembly of the hypochlorite cell voltage monitoring device.

As shown in FIG. 5, after manufacture, the hypochlorite cell voltage monitoring device may be coupled to a hypochlorite cell for voltage monitoring (block 506). One clamp ring of the clamp of the hypochlorite cell voltage monitoring device may be coupled to the anode side of the hypochlorite cell, and the opposite clamp ring of the clamp may be coupled to the cathode side of the hypochlorite cell. The voltage across the hypochlorite cell is displayed on the digital DC voltmeter of the hypochlorite cell voltage monitoring device and may be monitored (block 508) at single point in time or over a period of time. For example, the voltage may be compared to a threshold to determine if the cell is operating normally (decision block 510). If the hypochlorite cell is operating normally (that is, if the monitored voltage is within the threshold value), then the voltage may continue to be monitored (block 506). In some embodiments, the hypochlorite cell voltage monitoring device may be removed from the hypochlorite cell and coupled to another hypochlorite cell for monitoring of the other cell. In this manner, hypochlorite cell voltage monitoring device may advantageously provide portability and monitoring of multiple hypochlorite cells at the same or different sites.

If the cell is not operating normally (for example, if the voltage across the hypochlorite cell is outside the threshold value by a certain percentage), then the hypochlorite cell may be repaired or replaced. For example, an electrode in the hypochlorite cell may be cleaned or replaced.

In some embodiments, multiple hypochlorite cell voltage monitoring devices may be manufactured and installed on multiple hypochlorite cells. In some embodiments, the hypochlorite cell voltage monitoring device may include a wireless network interface for transmitting the voltage value measured by the digital DC voltmeter to a remote compute (for example, a laptop, tablet computer, or smartphone) via a wireless network.

### EXAMPLES

The following examples are included to demonstrate embodiments of the disclosure. It should be appreciated by those of skill in the art that the techniques and compositions disclosed in the example which follows represents techniques and compositions discovered to function well in the practice of the disclosure, and thus can be considered to constitute modes for its practice. However, those of skill in the art should, in light of the present disclosure, appreciate that many changes can be made in the specific embodiments which are disclosed and still obtain a like or a similar result without departing from the spirit and scope of the disclosure.

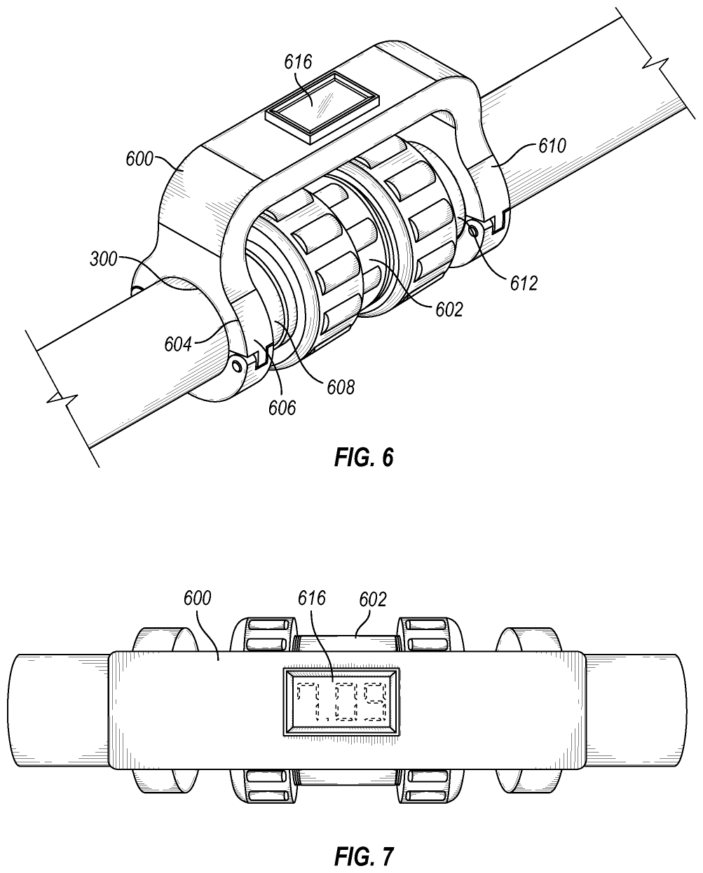

FIG. 6 is a diagram of a hypochlorite cell voltage monitoring device 600 coupled to a hypochlorite cell 602 via a clamp 604 in accordance with an embodiment of the disclosure. As shown in FIG. 6, a first clamp ring 606 is coupled to one side 608 (for example, anode side) of the hypochlorite cell while the second clamp ring 610 is coupled to the other side 612 (for example cathode side) of the hypochlorite cell. The digital DC voltmeter 616 of the hypochlorite cell voltage monitoring device 600 is powered by the circuit completed by the clamps.

FIG. 7 is a diagram showing operation of the digital DC voltmeter 616 of the hypochlorite cell voltage monitoring device 600 when coupled to the hypochlorite cell 602 in accordance with an embodiment of the disclosure. The digital DC voltmeter 616 may display the voltage across the hypochlorite cell 602, thus providing an indicator of the performance of the cell 602.

Ranges may be expressed in the disclosure as from about one particular value, to about another particular value, or both. When such a range is expressed, it is to be understood that another embodiment is from the one particular value, to the other particular value, or both, along with all combinations within said range.

Further modifications and alternative embodiments of various aspects of the disclosure will be apparent to those skilled in the art in view of this description. Accordingly, this description is to be construed as illustrative only and is for the purpose of teaching those skilled in the art the general manner of carrying out the embodiments described in the disclosure. It is to be understood that the forms shown and described in the disclosure are to be taken as examples of embodiments. Elements and materials may be substituted for those illustrated and described in the disclosure, parts and processes may be reversed or omitted, and certain features may be utilized independently, all as would be apparent to one skilled in the art after having the benefit of this description. Changes may be made in the elements described in the disclosure without departing from the spirit and scope of the disclosure as described in the following claims. Headings used in the disclosure are for organizational purposes only and are not meant to be used to limit the scope of the description.

What is claimed is:

1. A hypochlorite cell voltage monitoring device for monitoring voltage across a hypochlorite cell, comprising:
a clamp comprising a first clamp ring comprising a first voltage receiver and a second clamp ring opposite the first clamp ring and comprising a second voltage receiver, wherein the first clamp ring comprises a diameter selected to clamp to a first side of a hypochlorite cell and the second clamp ring comprises a diameter selected to clamp to a second side of the hypochlorite cell;
a housing adjacent to the clamp and comprising a first side and a second side opposite the first side; and
a digital direct current (DC) voltmeter disposed in the first side of the housing, and electrically connected to the first voltage receiver and the second voltage receiver such that the digital direct current (DC) voltmeter is operable to measure a voltage across the first voltage receiver and the second voltage receiver, wherein the digital direct current (DC) voltmeter comprises a display.

2. The hypochlorite cell voltage monitoring device of claim 1, wherein the clamp and the housing are formed as a single component.

3. The hypochlorite cell voltage monitoring device of claim 1, wherein the clamp is formed from a polymer.

4. The hypochlorite cell voltage monitoring device of claim 1, wherein the housing is formed from a polymer.

5. The hypochlorite cell voltage monitoring device of claim 1, wherein the first clamp ring and second clamp ring each comprises a hinge and a fastener coupled to the hinge.

6. The hypochlorite cell voltage monitoring device of claim 5, wherein the first clamp ring and second clamp ring each comprises an interlocking portion opposite the hinge.

7. The hypochlorite cell voltage monitoring device of claim 1, wherein the hypochlorite cell voltage monitoring device does not include a power source.

8. A method of monitoring voltage across a hypochlorite cell, comprising:
attaching a first clamp ring of a clamp of a hypochlorite cell voltage monitoring device to a first side of the hypochlorite cell;
attaching a second clamp ring of the clamp of the hypochlorite cell voltage monitoring device to the second side of the hypochlorite cell, wherein the hypochlorite cell voltage monitoring device comprises:
the clamp comprising the first clamp ring comprising a first voltage receiver and the second clamp ring comprising a second voltage receiver;
a housing adjacent to the clamp and comprising a first side and a second side opposite the first side; and
a digital direct current (DC) voltmeter disposed in the first side of the housing, and electrically connected to the first voltage receiver and the second voltage receiver such that the digital direct current (DC) voltmeter is operable to measure a voltage across the first voltage receiver and the second voltage receiver, wherein the digital direct current (DC) voltmeter comprises a display; and
monitoring the voltage across the hypochlorite cell on the display of the digital DC voltmeter.

9. The method of claim 8, wherein the clamp and the housing are formed as a single component.

10. The method of claim 8, wherein the clamp is formed from a polymer.

11. The method of claim 8, wherein the housing is formed from a polymer.

12. The method of claim 8, wherein first clamp ring and second clamp ring each comprises a hinge and a fastener coupled to the hinge.

13. The method of claim 12, wherein the first clamp ring and second clamp ring each comprises an interlocking portion opposite the hinge.

14. The method of claim 8, wherein the hypochlorite cell voltage monitoring device does not include a power source, the method comprising powering the hypochlorite cell voltage monitoring device using the hypochlorite cell.

15. The method of claim 8, wherein the hypochlorite cell is a first hypochlorite cell, the method comprising:
detaching the first clamp ring of the clamp of the hypochlorite cell voltage monitoring device from the first side of the first hypochlorite cell;
detaching the second clamp ring of the clamp of the hypochlorite cell voltage monitoring device from the second side of the hypochlorite cell;
attaching the first clamp ring of a clamp of a hypochlorite cell voltage monitoring device to a first side of a second hypochlorite cell;
attaching a second clamp ring of the clamp of the hypochlorite cell voltage monitoring device to the second side of a second hypochlorite cell; and
monitoring the voltage across the second hypochlorite cell on the display of the digital DC voltmeter.

16. A method of manufacturing a hypochlorite cell voltage monitoring device for monitoring voltage across a hypochlorite cell, the method comprising:
printing, using a three-dimensional printer, a single component comprising a clamp and a housing, the clamp comprising a first clamp ring and a second clamp ring opposite the first clamp ring, wherein the first clamp ring comprises a diameter selected to clamp to a first side of the hypochlorite cell and the second clamp ring comprises a diameter selected to clamp to a second side of the hypochlorite cell, wherein the housing comprises a first side and a second side opposite the first side;
installing a first voltage receiver in the first clamp ring and a second voltage receiver in the second clamp ring;
installing a digital direct current (DC) voltmeter in the housing; and
electrically connecting the digital DC voltmeter to the first voltage receiver and second voltage receiver.

17. The method of claim 16, wherein the clamp and the housing are formed from a polymer.

18. The method of claim 16, wherein the first clamp ring and second clamp ring each comprises a hinge and a fastener coupled to the hinge.

19. The method of claim 18, wherein the first clamp ring and second clamp ring each comprises an interlocking portion opposite the hinge.

20. The method of claim 16, wherein the hypochlorite cell voltage monitoring device does not include a power source.
